(19) United States
(12) Patent Application Publication
(10) Pub. No.: US 2025/0227917 A1
(43) Pub. Date: Jul. 10, 2025

(54) SEMICONDUCTOR DEVICE AND METHOD OF FABRICATING THE SAME

(71) Applicant: Fujian Jinhua Integrated Circuit Co., Ltd., Quanzhou City (CN)

(72) Inventors: Janbo Zhang, Quanzhou City (CN); Yirong Xu, Quanzhou City (CN); Li-Wei Feng, Quanzhou City (CN)

(73) Assignee: Fujian Jinhua Integrated Circuit Co., Ltd., Quanzhou City (CN)

(21) Appl. No.: 18/649,999

(22) Filed: Apr. 29, 2024

(30) Foreign Application Priority Data
Jan. 10, 2024 (CN) 202410038150.5

(51) Int. Cl. H10B 12/00

(52) U.S. Cl. CPC H10B 12/482; H10B 12/02; H10B 12/315

(57) ABSTRACT

The present disclosure provides a semiconductor device and a method of fabricating the same, including a substrate, a plurality of bit lines, a plurality of first spacer structures and a plurality of second spacer structures. The substrate includes a plurality of active areas. The bit lines are disposed on the substrate, across the active areas. The first spacer structures are respectively disposed on two opposite sidewalls of each of the bit lines, respectively. The second spacer structures are disposed on the substrate and connect to ends of the first spacer structures respectively, wherein materials of the first spacer structures are at least partially different from that of the second spacer structures.

### BACKGROUND OF THE INVENTION

### 1. Field of the Invention

The present invention generally relates to a semiconductor device and a method of fabricating the same, and more particularly, to a semiconductor device including bit lines and bit line spacers, and a method of fabricating the same.

### 2. Description of the Prior Art

With the trend of miniaturization of various electronic products, the design of semiconductor devices must also meet the requirements of high integration and high density. Under the current mainstream of development trend, dynamic random access memories (DRAMs) having recessed gate structures have gradually replaced the DRAMs having only planar gate structures due to longer carrier channel length for the same semiconductor substrate so as to reduce current leakage of capacitor structures. In general, a DRAM cell with a recessed gate structure includes a transistor component and a charge storage device to receive voltage signals from bit lines and word lines. However, due to the limitations of current processing technologies, there are still many defects in currently available DRAM cells with recessed gate structures, which need to be further improved to effectively improve the performance and reliability of related memory devices.

### SUMMARY OF THE INVENTION

An object of the present disclosure is to provide a semiconductor device and a fabricating method thereof, in which two different spacer structures are respectively disposed within a peripheral region and within a cell region, for providing various isolations. Thus, the semiconductor device of the present disclosure may therefore gain better structure reliability to achieve an optimized operation and performance.

Another object of the present invention is to provide a semiconductor device including a substrate, a plurality of bit lines, a plurality of first spacer structures and a plurality of second spacer structures. The substrate includes a plurality of active areas. The bit lines are disposed on the substrate, across the active areas. The first spacer structures are respectively disposed on two opposite sidewalls of each of the bit lines, respectively. The second spacer structures are disposed on the substrate and connect to ends of the first spacer structures respectively, wherein materials of the first spacer structures are at least partially different from that of the second spacer structures.

Another object of the present invention is to provide a method of fabricating a semiconductor device including the following steps. A substrate is provided, and the substrate includes a plurality of active areas. A plurality of bit lines is formed on the substrate, across the active areas. A plurality of first spacer structures is formed on the substrate, at two opposite sidewalls of each of the bit lines respectively. A plurality of second spacer structures is formed on the substrate, with one end of each of the second spacer structures being connected to one end of each of the first spacer structures, wherein materials of each of the first spacer structures are at least partially different from that of each of the second spacer structures.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 3 are schematic diagrams illustrating a semiconductor device according to a first embodiment of the present disclosure, wherein:

FIG. 1 illustrates a top view of the semiconductor device;

FIG. 2 illustrates a cross-sectional view taken along a cross line A-A′ in FIG. 1; and

FIG. 3 illustrates a cross-sectional view taken along a cross line B-B′ in FIG. 1.

FIG. 4 to FIG. 15 are schematic diagrams illustrating a method of fabricating the semiconductor device according to the first embodiment of the present disclosure, wherein:

FIG. 4 illustrates a cross-sectional view of a semiconductor device after forming plug holes;

FIG. 5 illustrates another cross-sectional view of a semiconductor device after forming plug holes;

FIG. 6 illustrates a cross-sectional view of a semiconductor device after forming a semiconductor material layer;

FIG. 7 illustrates another cross-sectional view of a semiconductor device after forming a semiconductor material layer;

FIG. 8 illustrates a cross-sectional view of a semiconductor device after performing a first etching process;

FIG. 9 illustrates another cross-sectional view of a semiconductor device after performing a first etching process;

FIG. 10 illustrates a cross-sectional view of a semiconductor device after forming a dielectric material layer;

FIG. 11 illustrates another cross-sectional view of a semiconductor device after forming a dielectric material layer;

FIG. 12 illustrates a cross-sectional view of a semiconductor device after forming first spacer structures;

FIG. 13 illustrates another cross-sectional view of a semiconductor device after forming first spacer structures;

FIG. 14 illustrates a cross-sectional view of a semiconductor device after performing a second etching process; and

FIG. 15 illustrates another cross-sectional view of semiconductor device after performing a second etching process.

FIG. 16 is a schematic diagram illustrating a top view of a semiconductor device according to a second embodiment of the present disclosure.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

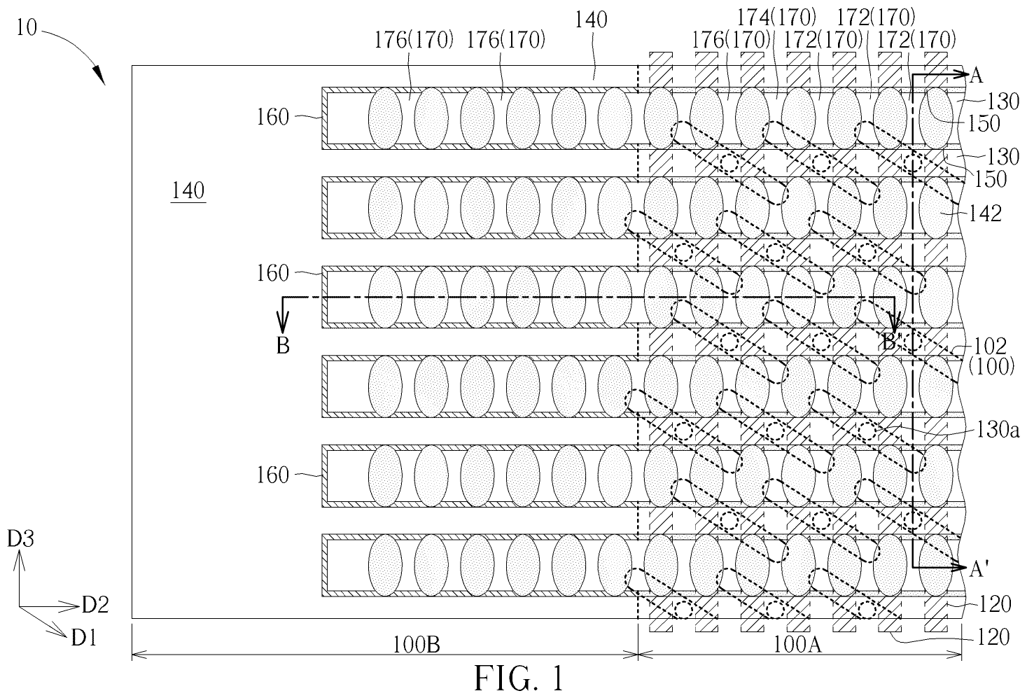

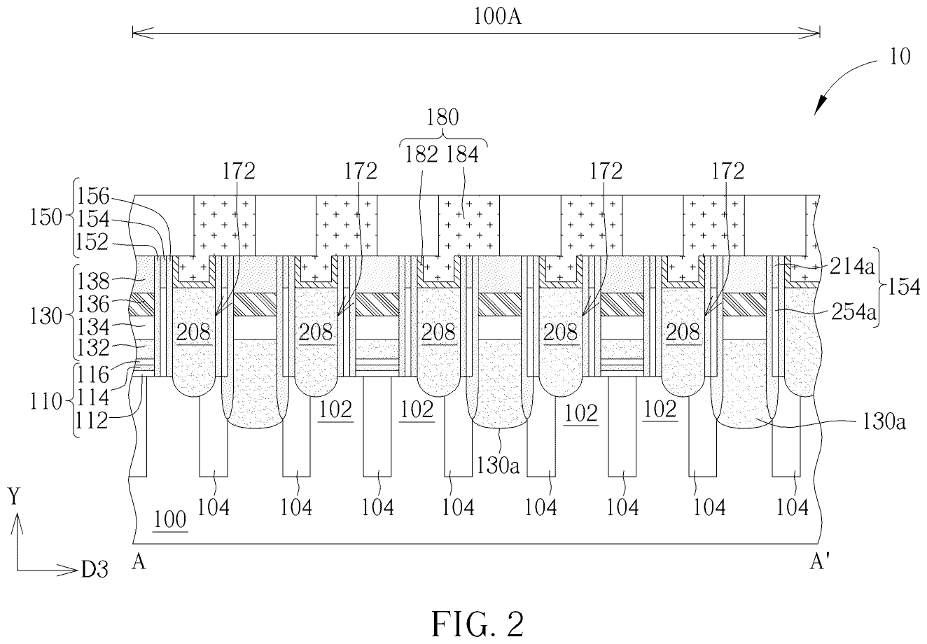

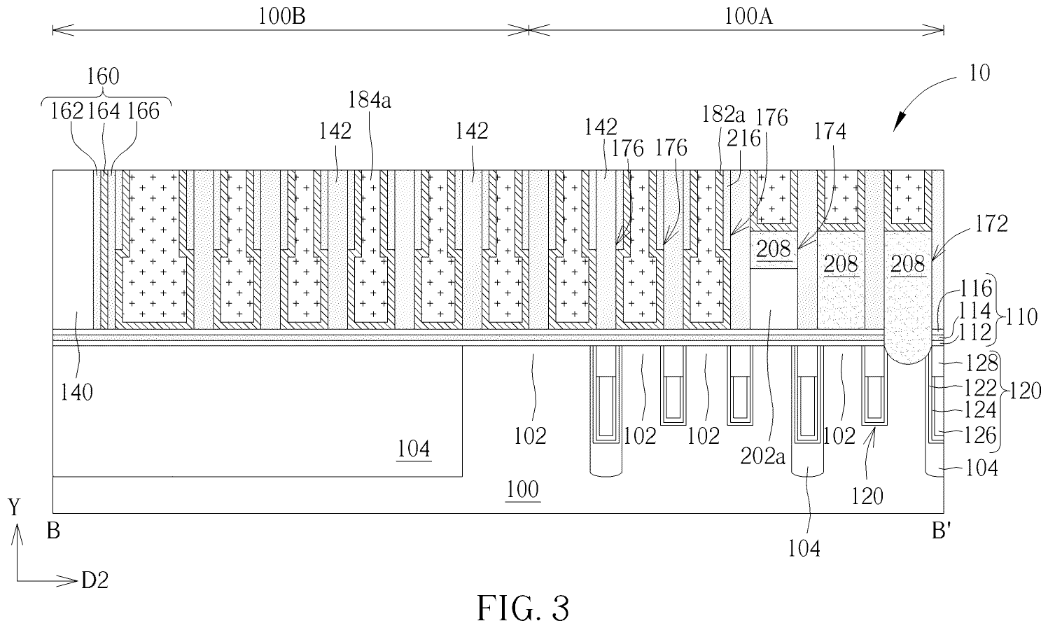

Please refer to FIG. 1 to FIG. 3, which are schematic diagrams illustrating a semiconductor device 10 according to a first embodiment of the present disclosure, with FIG. 1 showing a top view of the semiconductor device 10, and with FIG. 2 and FIG. 3 showing a cross-sectional view of the semiconductor device 10. The semiconductor device 10 includes a substrate 100, a plurality of bit lines 130, a plurality of first spacer structures 150, and a plurality of second spacer structures 160. The substrate 100 for example includes a silicon substrate, a silicon-containing substrate (e.g., SiC or SiGe), an epitaxial silicon substrate, a silicon-on-insulator (SOI) substrate, or a substrate formed of any other suitable materials, but it is not limited thereto. The substrate 100 further includes a plurality of shallow trench isolations 104 (for example including silicon oxide) disposed therein, to define a plurality of active areas 102 in a direction D1, within the substrate 100. The plurality of bit lines 130 is separately disposed on the substrate 100 in a first direction D2, to intersect plural of the active areas 102 at the same time. The first spacer structures 150 are respectively disposed on two opposite sidewalls of each of the bit lines 130. The second spacer structures 160 are disposed on the substrate 100, with one end of each of the second spacer structures 160 connecting to an end-portion of each of the first spacer structures 150. It is noted that materials of each first spacer structure 150 are at least partially different from that of each second spacer structure 160, for example respectively including an insulating material and a conductive material, to achieve different isolations in various regions. In this way, the structural reliability of the semiconductor device 10 will be dramatically improved, thereby gaining an optimized operation and performance.

In one embodiment, the second spacer structures 160 are respectively disposed on sidewalls of a plurality of dummy bit lines 140 also in the first direction D2. Since one end of each of the dummy bit lines 140 is connected to the end-portion of each of the bit lines 130 in the first direction D2, and another end of each of the dummy bit lines 140 is connected to each other in a second direction D3, each of the second spacer structures 160 is therefore obtained an U-shaped structure from a top view as shown in FIG. 1, but not limited thereto. On the other hand, each of the first spacer structures 150 includes an I-shaped structure from a top view. It is noted that, in order to clearly illustrate the arrangement of specific elements (for example the word lines 120 and the bit lines 130), some elements such as the detailed features of the first spacer structures 150 and the second spacer structures 160 are omitted in FIG. 1 of the present embodiment, and those who skilled in the art should fully realize the location of the omitted elements in FIG. 1 through the cross-sectional views as shown in FIG. 2 and FIG. 3.

As shown in FIG. 2 and FIG. 3, each of the first spacer structures 150 precisely includes a first spacer layer 152 (for example including silicon nitride or silicon carbonitride), an insulating middle-layer 154, and a second spacer layer 156 (for example including silicon nitride or silicon carbonitride) stacked in sequence on the sidewall of each bit line 130, and each of the second spacer structures 160 precisely includes a third spacer layer 162 (for example including silicon nitride or silicon carbonitride), a conductive middle-layer 164, and a fourth spacer layer 166 (for example including silicon nitride or silicon carbonitride) stacked in sequence on the sidewall of each dummy bit line 140. The insulating middle-layer 154 further includes a first dielectric material 254a (for example including silicon nitride or silicon carbonitride) and a second dielectric material (for example including silicon oxide or silicon oxynitride) stacked in sequence in the vertical direction “Y”, and the conductive middle-layer 164 for example includes a material like titanium, titanium nitride, tantalum, or tantalum nitride, but not limited thereto. Since the end of each dummy bit line 140 is connected to the end-portion of each bit line 130, the end of the first spacer layer 152 of each first spacer structure 150 and the end of the third spacer layer 162 of each second spacer structure 160, as well as the end of the second spacer layer 154 of each first spacer structure 150 and the end of the fourth spacer layer 164 of each second spacer structure 160, are also connected with each other, but not limited thereto. In one embodiment, the first spacer layer 152 and the third spacer layer 162 may include the same material, and/or the second spacer layer 154 and the fourth spacer layer 164 may include the same material, such that, the first spacer layer 152 and the third spacer layer 162, and/or the second spacer layer 154 and the fourth spacer layer 164, are continuously extended in the first direction D2 or disposed in a monolithic manner.

Further in view of FIG. 1, the substrate 100 of the semiconductor device 10 further includes a cell region 100A with a relative higher elemental integration, and a periphery region 100B with a relative lower elemental integration, with the cell region 100A and the periphery region 100B being adjacent to each other, but not limited thereto. The aforementioned active areas 102, the bit lines 130 and the first spacer structures 150 are all disposed in the cell region 100A, and the dummy bit lines 140 and the second spacer structures 160 are disposed in the periphery region 100B. Also, a plurality of word lines 120 is further disposed within the substrate 100, within the cell region 100A, with each of the word lines 120 separately disposed in the second direction D3. Those skilled in the art should fully realize that the extending directions of the active areas 102, the word lines 120, and the bit lines 130 are all different from each other. For example, the extending direction (the second direction D3) of the word lines 120 may be perpendicular to the extending direction (the first direction D2) of the bit lines 130, to simultaneously intersect several active areas 102 and the bit lines 130.

Precisely speaking, as shown in FIG. 1 and FIG. 2, each of the bit lines 130 includes a semiconductor layer 132 (for example including a semiconductor material like doped polysilicon or doped amorphous silicon), a barrier layer 134 (for example including a barrier material like titanium and/or titanium nitride, tantalum and/or tantalum nitride), a metal layer 136 (for example including a metal material like tungsten, aluminum or copper), and a capping layer 138 (for example including an insulating material like silicon oxide, silicon nitride or silicon oxynitride) stacked in sequence. The bit lines 130 are basically disposed on an insulating layer 110 disposed on the substrate 100, and a portion of the semiconductor layer 132 is extended into the substrate 100 to serve as bit line contacts (BLCs) 130a. Accordingly, the bit lines 130 are electrically connected to the active areas 102 through the bit line contacts 130a which are disposed underneath in a monolithic manner, thereby receiving and transmitting the signals from the substrate 100. On the other hands, as shown in FIG. 1 and FIG. 3, each of the word lines 120 includes a dielectric layer 122, a gate dielectric layer 124, and a gate layer 126 stacked in sequence, and a capping layer 128 stacked on the gate layer 126, with a top surface of the capping layer 128 being coplanar with the top surface of the substrate 100. Then, each of the word lines 120 will therefore serve as a buried word line (BWL), and which is isolated from each bit line 130 through the insulating layer 110 disposed over the substrate 100. In one embodiment, the insulating layer 110 preferably includes a multilayer structure including an oxide layer 112-a nitride layer 114-an oxide layer 116 (oxide-nitride-oxide, ONO) stacked in sequence, but not limited thereto.

Further in view of FIG. 1, FIG. 2, and FIG. 3, the semiconductor device 10 further includes a plurality of plugs 170, respectively disposed between two adjacent ones of the bit lines 130, or between two adjacent ones of the dummy bit lines 140. The plugs 170 are electrically isolated from each other in the first direction D2 through a plurality of isolating structures 142 disposed therebetween. The plugs 170 further includes a plurality of first plugs 172 and a plurality of second plugs 176, with the first plugs 172 being alternately arranged with the bit lines 130 in the second direction D3, and with the second plugs 176 being alternately arranged with the bit lines 130 or the dummy bit lines 140 in the second direction D3. Accordingly, the first spacer structures 150 may be disposed between the first plugs 172 and the bit lines 130, and the second spacer structures 160 may be disposed between the second plugs 176 and the bit lines 130, or between the second plugs 176 and the dummy bit lines 160.

Precisely speaking, a bottom of each of the first plugs 172 partially extends into the substrate 100 to electrically connect each of the active areas 102, and a conductive pad 180 is further disposed on a top of each of the first plugs 172, as shown in FIG. 2. Accordingly, the first plugs 172 are configured as storage node contacts (SNCs) of the semiconductor device 10 to electrically connect to subsequently formed storage nodes (SN) respectively. In one embodiment, the first plugs 172 for example include a semiconductor material like doped polysilicon or doped amorphous silicon, or a low-resistance metal material like aluminum, titanium, copper or tungsten, and preferably include the same semiconductor material 208 as that of the semiconductor layer 132 of each bit line 130, but not limited thereto. In another embodiment, the conductive pad 180 for example includes a barrier layer 182 and a contact metal layer 184 stacked in sequence. The barrier layer 182 for example includes a barrier material like titanium, titanium nitride, tantalum, tantalum nitride, tungsten nitride or other suitable material, and preferably includes the same material as that of the conductive middle-layer 164. The contact metal layer 184 for example includes a low-resistance metal material like aluminum, titanium, copper, or tungsten, and preferably includes tungsten, but not limited thereto.

On the other hand, the second plugs 176 are disposed on the insulating layer 110 over the substrate 100, without contacting any active area 102, as shown in FIG. 3. Accordingly, the second plugs 176 are configured as dummy plugs of the semiconductor device 10, and which are used to balance the elemental integration in the cell region 100A and in the periphery region 100B during fabricating the plugs 170, so as to improve the producing yield thereof. Precisely speaking, the second plugs 176 and the isolation structures 142 are alternately arranged in the first direction D2, and each of the second plugs 176 has a cross-section with a smaller top and a bigger bottom. Precisely speaking, each of the second plugs 176 comprises a top surface and a bottom surface in the cross-section, and a width of the top surface is smaller than a width of the bottom surface. That is, the semiconductor device 10 further includes a plurality of dielectric layers 216 disposed on an upper sidewall of each of the second plugs 176, with the dielectric layer 216 physically contacting the isolation structures 142 and an upper portion of the third spacer layer 162 of the second spacer structure 160, for further isolating any adjacent second plugs 176 and also defining the cross-section of the second plugs 176. In one embodiment, each of the second plugs 176 further includes a first conductive material 182a and a second conductive material 184a stacked in sequence. The first conductive material 182a for example includes a barrier material like titanium, titanium nitride, tantalum, tantalum nitride, tungsten nitride, or other suitable material, and preferably includes the same material as that of the conductive middle-layer 164. The second conductive material 184a for example includes a low-resistance metal material like aluminum, titanium, copper, or tungsten, and preferably include the same conductive material as that of the contact metal layer 184, but not limited thereto. Also, in another embodiment, the plugs 170 further include at least one third plug 174 disposed between the second plugs 176 and the first plugs 172. The third plug 174 is also disposed on the insulating layer 110 over the substrate 100, without contacting any active area 102. In one embodiment, the third plug 174 for example includes the insulating material 202a and the semiconductor material 208 stacked in sequence in the vertical direction “Y”, to configure as a dummy plug of the semiconductor device 10. The aforementioned semiconductor material 208 is for example the same as the semiconductor material 208 of the first plugs 172, but not limited thereto.

According to the semiconductor device 10 of the present embodiment, the first spacer structures 150 having the insulating middle-layer 154 and the second spacer structures 160 having the conductive middle-layer 164 are respectively disposed on the sidewalls of the bit lines 130 and the dummy bit lines 140, with materials of the spacer structures 150 and the second spacer structures 160 being at least partially different from each other. In this way, the first spacer structures 150 and the second spacer structures 160 will therefore achieve various isolation functions in the cell region 100A and in the periphery region 100B of the semiconductor device 10, to improve the structural reliability of the semiconductor device 10, and to gain an optimized operation and performance thereby. On the other hands, the first spacer layer 152 and the second spacer layer 156 disposed at two sides of the insulating middle-layer 154, and the third spacer layer 162 and the fourth spacer layer 166 disposed at two sides of the conductive middle-layer 164 may include the same material or may be monolithic, so as to simplify the fabricating process of the first spacer structures 150 and the second spacer structures 160. With these performances, the semiconductor device 10 may be functioned like a dynamic random access memory (DRAM) device, with at least one capacitor (not shown in the drawings) disposed over the first plugs 172 and at least one transistor (not shown in the drawings) disposed within the substrate 100 together forming the smallest memory cell of the DRAM array, for receiving the voltage signals from the bit lines 130 and the word lines 120.

In order to make those having ordinary skills in the art easily understand the semiconductor device 10 according to the present disclosure, a method of fabricating the semiconductor device 10 according to the present disclosure will be further described as follows.

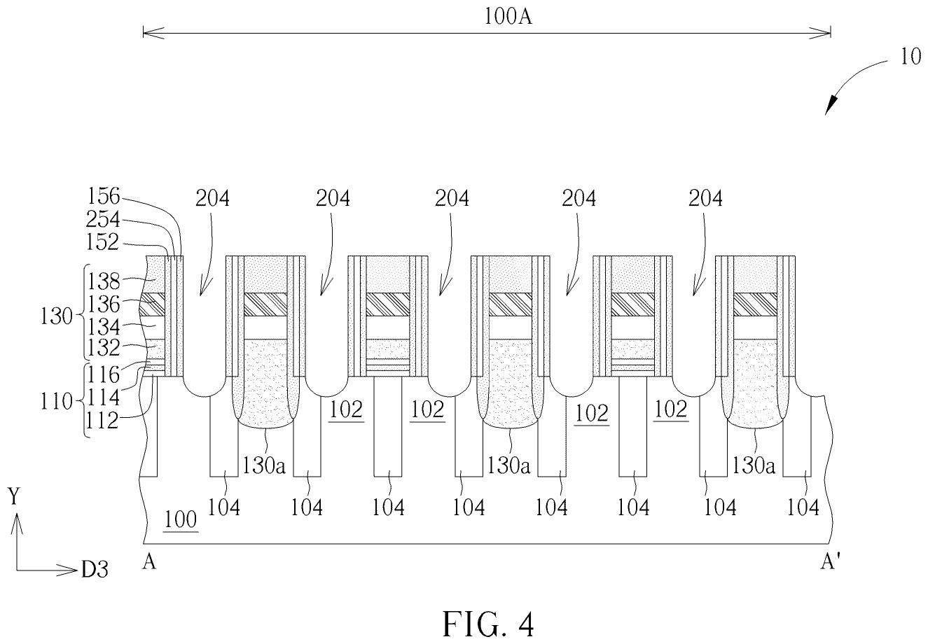

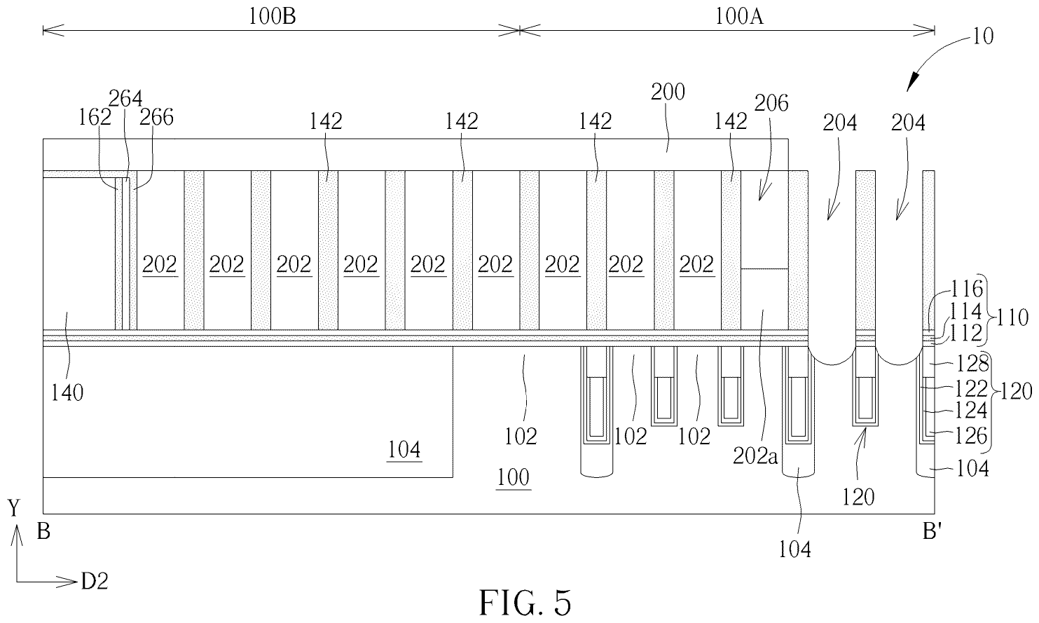

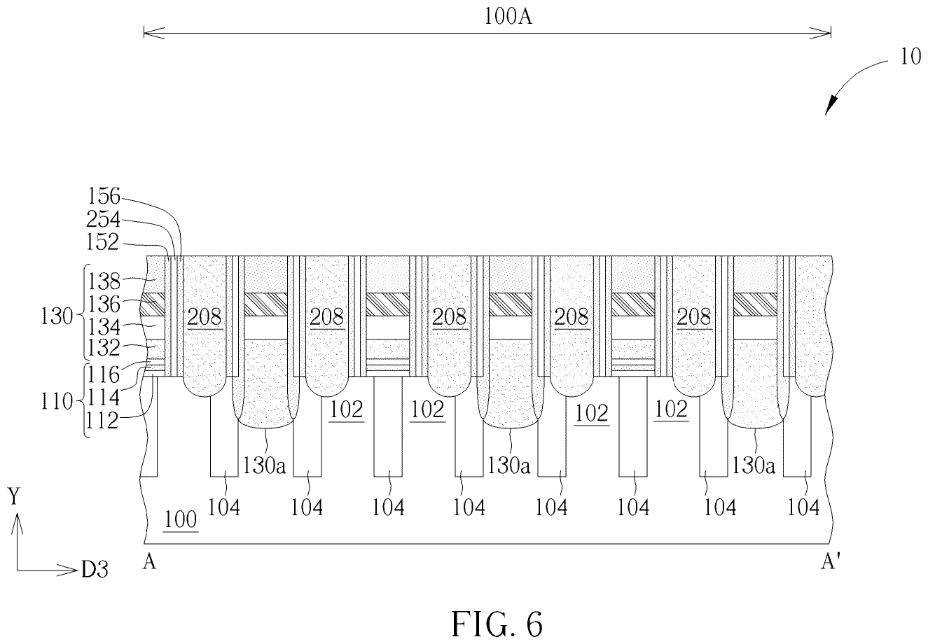

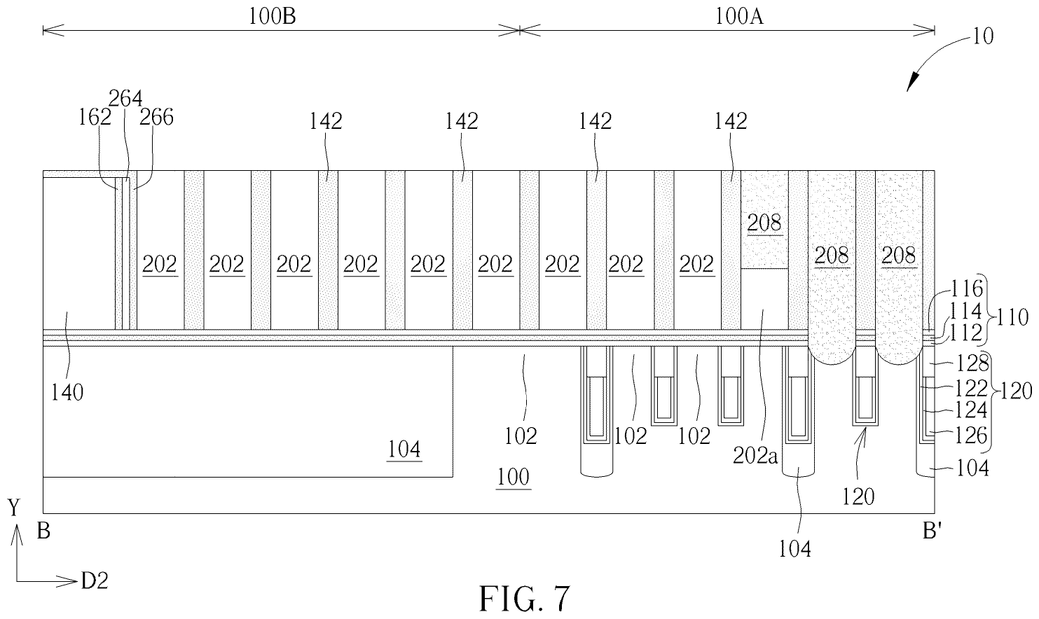

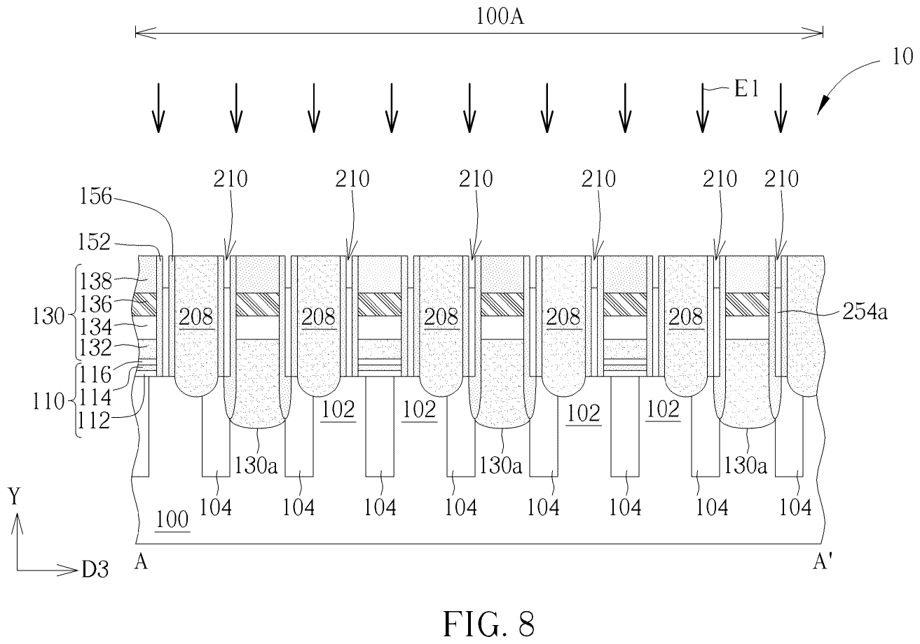

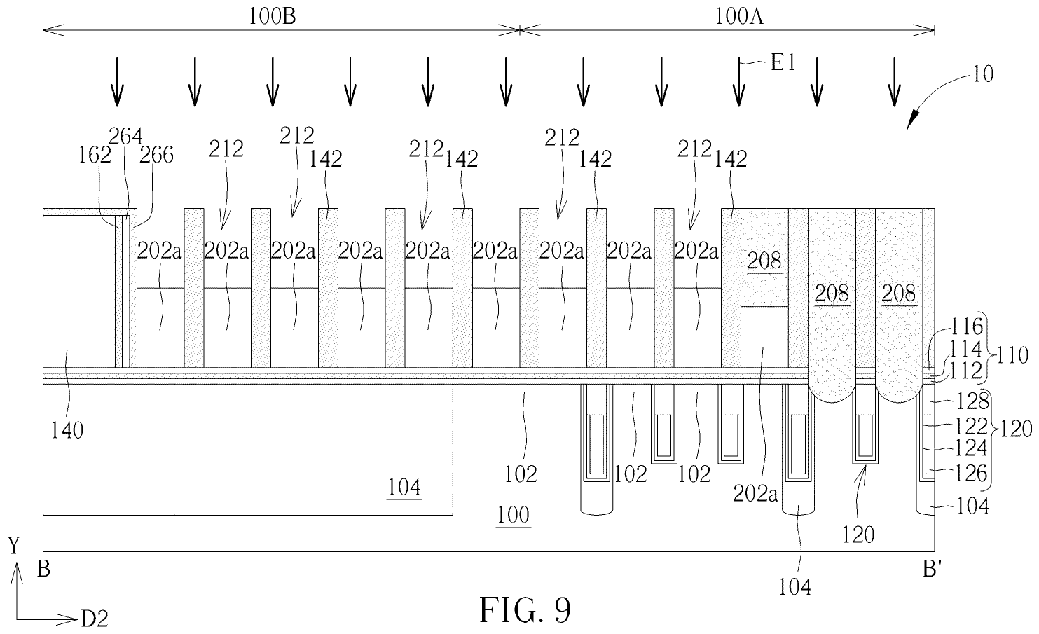

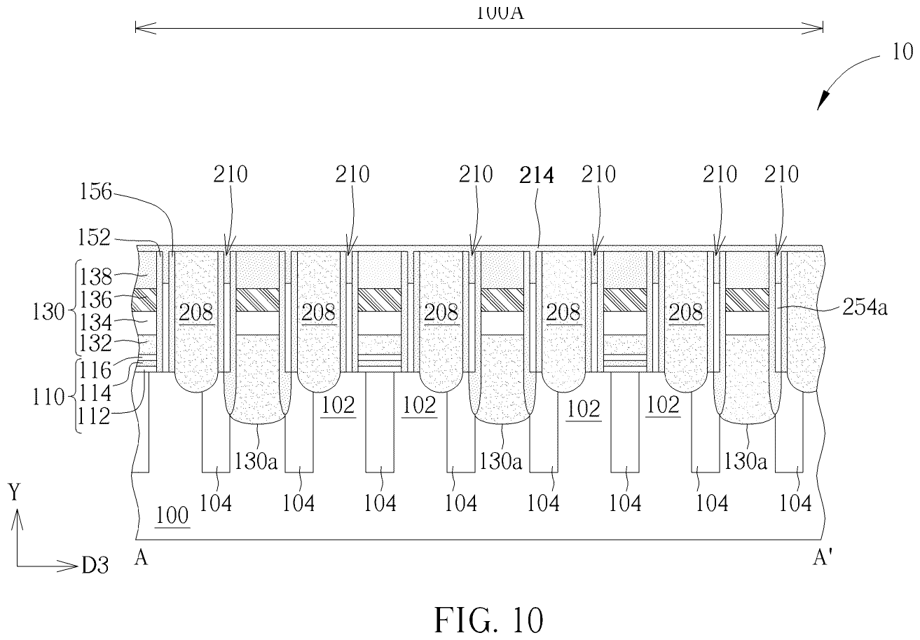

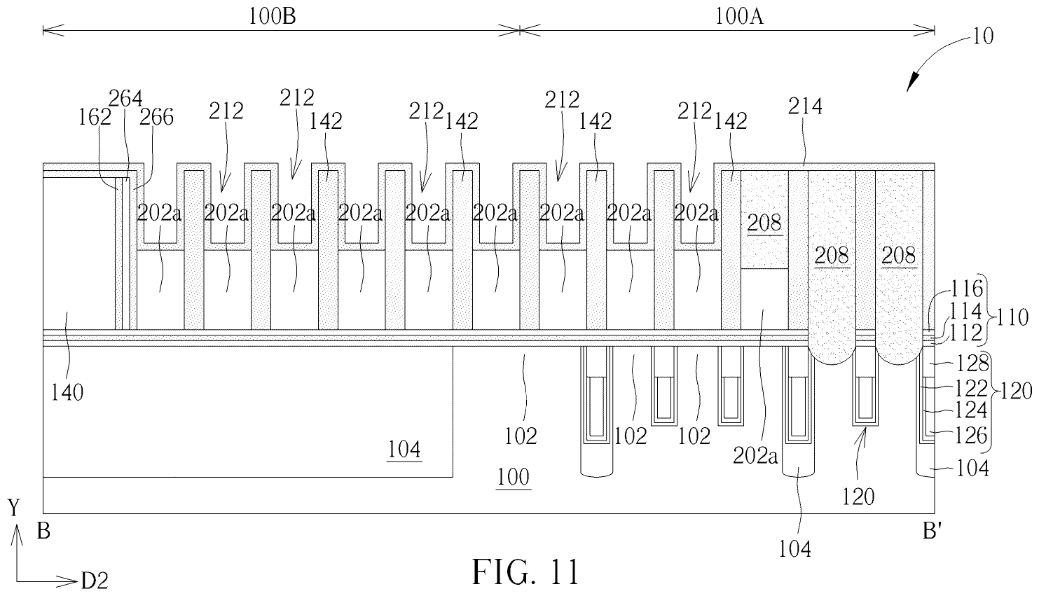

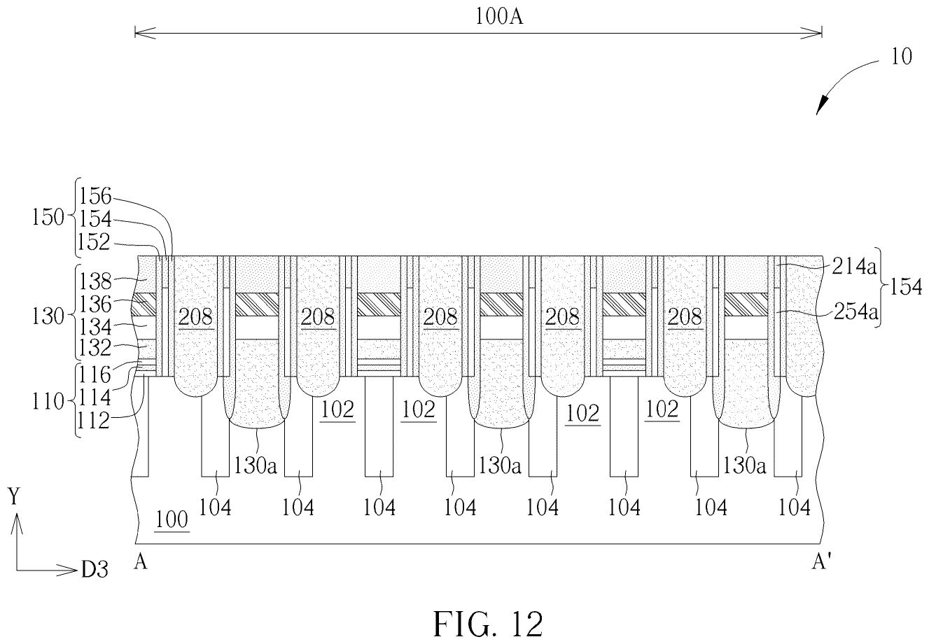

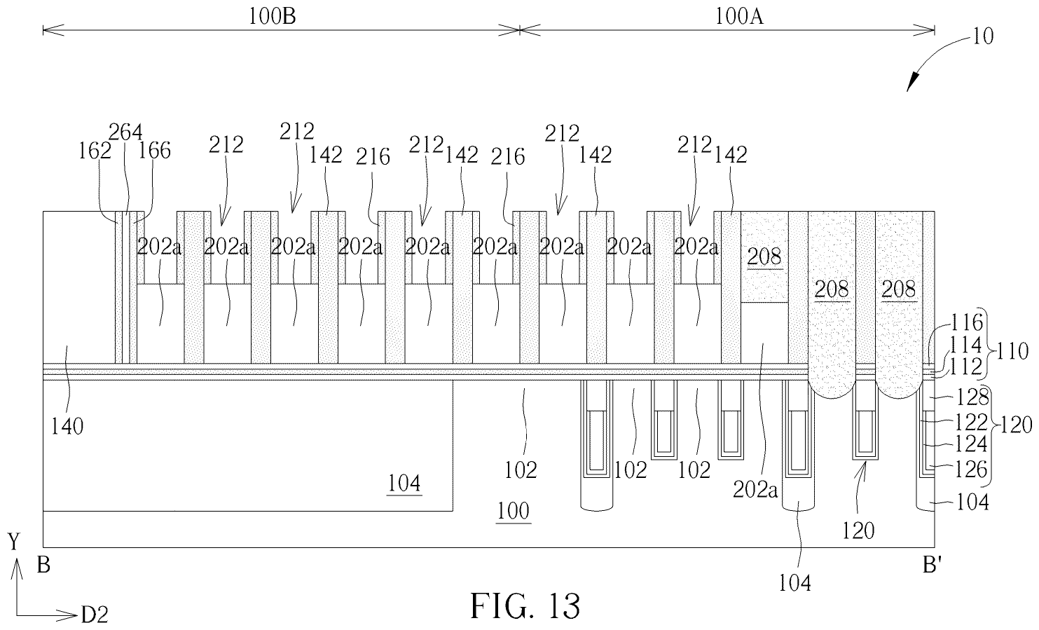

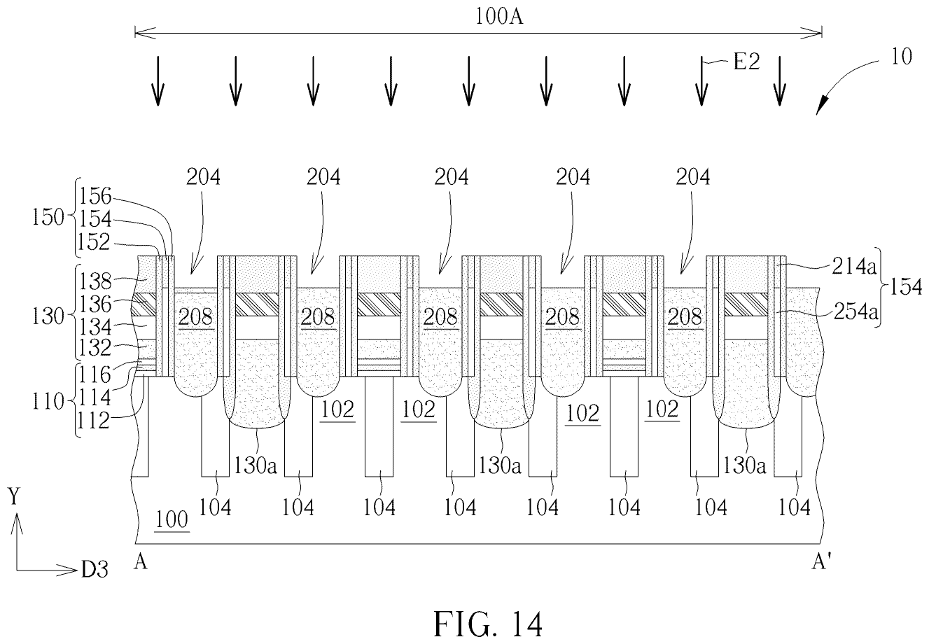

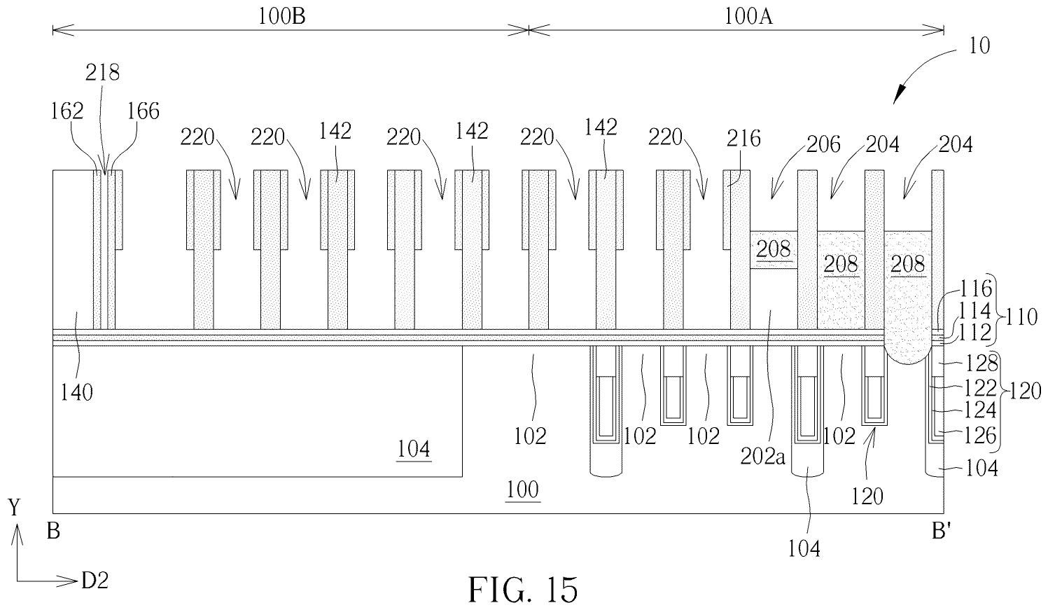

Please refer FIG. 4 to FIG. 15, which are schematic diagrams illustrating a method of fabricating a semiconductor device 10 according to the preferable embodiment of the present disclosure, with FIG. 4, FIG. 6, FIG. 8, FIG. 10, FIG. 12, and FIG. 14 respectively illustrating a cross-sectional view of the semiconductor device 10 along a cross-line A-A′ during the fabricating process, and with FIG. 5, FIG. 7, FIG. 9, FIG. 11, FIG. 13, and FIG. 15 respectively illustrating a cross-sectional view of the semiconductor device 10 along a cross-line B-B′ during the fabricating process. Although a top view of the semiconductor device 10 during the fabricating process is not shown in the present embodiment, those who skilled in the art should fully realize the top view of the semiconductor device 10 in each step as reference to FIG. 1 as shown above.

Firstly, as shown in FIG. 4 and FIG. 5, the substrate 100 is provided, and the shallow trench isolation 104 is formed in the substrate 100 to define a plurality of the active areas 102 in the substrate 100. In one embodiment, the fabrication of the shallow trench isolation 104 is carried out by firstly forming a plurality of shallow trenches (not shown in the drawings) in the substrate 100 through performing an etching process, and at least one insulating material (such as including silicon oxide) is filled in the shallow trenches, to form the shallow trench isolation 104 having a top surface being coplanar with the top surface of the substrate 100, but not limited thereto. Next, a plurality of the word lines 120 is formed in the second direction D3, within the substrate 100. In one embodiment, the fabricating process of the word lines 120 includes but not limited to the following steps. Firstly, a plurality trenches (not shown in the drawings) is formed across plural active areas 102 and the shallow trench isolation 104, and a dielectric layer 122 covering an entire surface of each trench, a gate dielectric layer 124 covering the lower surface of each trench, a gate electrode 126 filled in the lower portion of each trench, and a capping layer 128 filled in the upper portion of each trench are formed in sequence. Then, the insulating layer 110, a plurality of the bit lines 130 extending in the first direction D2, and a plurality of the dummy bit lines 140 respectively connecting the end-portion of each of the bit lines 130 are formed on the substrate 100. Each of the bit lines 130 is electrically connected to the active areas 102 through a corresponding bit line contact 130 formed underneath. In one embodiment, the fabricating process of the bit lines 130 and the bit line contact 130 includes but not limited to the following steps. Firstly, a plurality of openings (not shown in the drawings) is formed through a mask (not shown in the drawings), with the openings penetrating through the insulating layer 110 to expose the top surface of the substrate 100, and a semiconductor material layer (not shown in the drawings, for example including a semiconductor material like doped polysilicon or doped amorphous silicon) is formed on the substrate 100 to fill in the openings. Following these, a barrier material layer (not shown in the drawings, for example including a barrier material like titanium and/or titanium nitride, tantalum and/or tantalum nitride), a metal material layer (not shown in the drawings, for example including a low-resistant metal material like tungsten, aluminum, copper), and a capping material layer (not shown in the drawings, for example including an insulating material like silicon oxide, silicon nitride or silicon oxynitride) are formed in sequence on the semiconductor material layer, and a patterning process is performed on the capping material layer, the metal material layer, the barrier material layer and the semiconductor material layer, to simultaneously form the bit lines 130 and the bit line contacts 130a. Then, a plurality of the isolation structures 142 are formed between the adjacent bit lines 130 and the adjacent dummy bit lines 140, and a deposition process and an etching back process are sequentially performed to form an insulating material layer 202 on the insulating layer 110, to fill in the rest space between the bit lines 130 and the dummy bit lines 140. In one embodiment, the insulating material layer 202 for example includes an insulating material like silicon oxide, silicon oxynitride, but is not limited thereto.

Then, further in view of FIG. 4 and FIG. 5, a mask layer 200 is formed on the insulating material layer 202, covering the periphery region 100B and a portion of the cell region 100A of the substrate 100, and an etching process is performed on the insulating material layer 202 through the mask layer 200, removing the insulating material layer 202 and forming a plurality of contact holes 204 exposing the corresponding active area 102 underneath, and at least one contact hole 206 without exposing any active area 102 and having the insulating material 202a of the insulating material layer 202 partially remained in the bottom. The contact holes 204 and the contact hole 206 are formed within the cell region 100A, but not limited thereto. It is noted that although only one contact hole 206 is illustrated in the drawings of the present embodiment, those who skilled in the arts should fully realized that a plurality of the contact holes 206 may be formed at the same time through the aforementioned etching process as reference to the top view of the semiconductor device 10 as shown I FIG. 1. Then, the mask layer 200 is completely removed.

It is also noted that, before forming the isolating structures 142, the first spacer layer 152 and a first material layer 254 are sequentially formed on the sidewalls of the bit lines 130, and a spacer material layer (not shown in the drawings) is formed to entirely cover the bit lines 130, the first spacer layer 152, and the first material layer 254. On the other hands, the third spacer layer 162 and a second material layer 264 are formed sequentially on the sidewalls of the dummy bit lines 140 while forming the first spacer layer 152 and the first material layer 254, and a spacer material layer 266 is formed to entirely cover the dummy bit lines 140, the third spacer layer 162 and the second material layer 264 while forming the spacer material layer. In one embodiment, the first spacer layer 152 and the third spacer layer 162 both having silicon nitride or silicon carbonitride are together formed through the same deposition process, the first material layer 254 and the second material layer 264 for example including silicon oxide or silicon oxynitride are together formed through the same deposition process, and the said spacer material layer and the spacer material layer 266 for example including silicon nitride or silicon carbonitride are together formed through the same deposition process. That is, the first spacer layer 152 and the third spacer layer 162, the first material layer 254 and the second material layer 264, and the said spacer material layer and the spacer material layer 266 may respectively include the same material, and continuously extend in a monolithic manner. Furthermore, the first spacer layer 152, the third spacer layer 162, the said spacer material layer, and the spacer material layer 266 preferably include the same material, but not limited thereto. It is noted that, while the etching process is performed, the said spacer material layer covering on top surfaces of the bit lines 130, the first spacer layer 152 and the first material layer 254 are also removed, to form the second spacer layer 156 as shown in FIG. 4, and the spacer material layer 266 covering on top surfaces of the dummy bit lines 140, the third spacer layer 162 and the second material layer 264 will not be removed due to being covered by the mask layer 200. Accordingly, the spacer material layer 266 is still remained on the top surfaces of the dummy bit lines 140, the third spacer layer 162 and the second material layer 264, as shown in FIG. 5.

As shown in FIG. 6 and FIG. 7, a deposition process is performed on the substrate 100, to form a semiconductor material layer (not shown in the drawings) filling in the plug holes 204, 206 and further covering the top surfaces of the bit lines 130, the dummy bit lines 140 and the isolating structures 142, and an etching back process is then performed to remove the semiconductor material layer covering on the top surfaces of the bit lines 130, the dummy bit lines 140 and the isolating structures 142, and to remain the semiconductor material 208 filled in the plug holes 204, 206. The semiconductor material 208 filled in the plug holes 206 is directly disposed over the insulating material 202a in the vertical direction “Y”.

As shown in FIG. 8 and FIG. 9, a first etching process E1 is performed, to partially remove a rest portion of the insulating material layer 202, and to form a plurality of plug holes 212 having the insulating material 202a of the insulating material layer 202 remained in the bottom thereof, without exposing the active areas 102 underneath. Also, the first material layer 254 with a similar material as the insulating material layer 202 is partially removed while performing the first etching process E1, to form a plurality of openings 210 between the first spacer layer 152 and the second spacer layer 156, with a portion of the dielectric material 254a of the first material layer 254 being still remained in the bottom of each opening 210. It is noted that, since the second material layer 264 also having similar material as the insulating material layer 202 is still covered by the spacer material layer 266, which is not removed while performing the first etching process E1, as shown in FIG. 9.

As shown in FIG. 10 and FIG. 11, a dielectric material layer 214 for example including a dielectric material like silicon nitride or silicon carbonitride, is formed on the substrate 100, conformally covering the exposed surfaces of the spacer material layer 266, the insulating structures 142 and the plug holes 212, and further covering the first spacer layer 152, the second spacer layer 156, the bit lines 130 and the semiconductor material 208 between the bit lines 130. The dielectric material layer 214 fills in the openings 210 between the first spacer layer 152 and the second spacer layer 156.

As shown in FIG. 12 and FIG. 13, a planarization process is performed on the dielectric material layer 214 shown in FIG. 11, to remove the dielectric material layer 214 covering on the spacer material layer 266, the isolating structures 142 and the semiconductor materials 208, and to form a plurality of dielectric layers 216 on an upper sidewall of the isolating structures 142 respectively. Meanwhile, the spacer material layer 266 having a similar material as the dielectric material layer 214 is also partially removed while performing the planarization process, to form the fourth spacer layer 166, thereby exposing the second material layer 264 between the third spacer layer 162 and the fourth spacer layer 166. On the other hand, the dielectric material layer 214 (as shown in FIG. 10) covering on the first spacer layer 152, the second spacer layer 156, the bit lines 130 and the semiconductor materials 208 are also removed while performing the planarization process, to only remain the dielectric materials 214a of the dielectric material layer 214 filled in the openings 210. Accordingly, the dielectric material 254a and the dielectric material 214a sequentially stacked between the first spacer layer 152 and the second spacer layer 156 together form the insulating middle-layer 154. Then, the insulating middle-layer 154, and the first spacer layer 152 and the second spacer layer 156 at two sides thereof together form the first spacer structure 150 as shown in FIG. 1 and FIG. 2.

As shown in FIG. 14 and FIG. 15, a second etching process E2 is performed to completely remove the insulating materials 202a remained in the gap between adjacent isolating structures 142, as well as the second material layer 264 having similar material as the insulating materials 202a, thereby forming a plurality of plug holes 220 exposing the top surfaces of the insulating layer 110, and forming an air-gap layer 218 between the third spacer layer 162 and the fourth spacer layer 166. On the other hands, the semiconductor materials 208 in the plug holes 204, 206 are also partially removed till not filled up the plug holes 204, 206 during the second etching process E2.

Following these, at least one deposition process is next performed on the substrate 100, to sequentially form a barrier material layer (not shown in the drawings) for example including a suitable barrier material like titanium, titanium nitride, tantalum, tantalum nitride or tungsten nitride, and a contact metal material layer (not shown in the drawings) for example including a low resistance metal like aluminum, titanium, copper or tungsten. Then, the barrier material layer will fill in the air-gap layer 218, and further cover on the exposed surfaces of the dummy bit lines 140, the dielectric layer 216, the plug holes 220, 204, 206 and the bit lines in a conformal manner, and the contact metal material layer will fill in the rest space of all of the plug holes 220, 204, 206, and further cover on the top surfaces of the dummy bit lines 140, the isolating structures 142, and the bit lines 130. After that, a patterning process is performed, to partially remove the contact metal material layer and the barrier material layer covered on the dummy bit lines 140, the isolating structures 142 and the bit lines 130, such that, the barrier material layer filled in the air-gap layer 218 will therefore form the conductive middle-layer 164. The conductive middle-layer 164, and the third spacer layer 163 and the fourth spacer layer 166 at two sides thereof will together form the second spacer structure 160 as shown in FIG. 1 and FIG. 3. On the other hands, the contact metal material layer and the barrier material layer filled in the plug holes 220 will therefore form a plurality of second plugs 176, the contact metal material layer and the barrier material layer filled in the plug holes 204, 206 will therefore form a plurality of conductive pads 180 which are in physical contact with a plurality of first plugs 172 and at least one third plug 174 formed underneath. Accordingly, the fabrication of the plugs 170 shown in FIG. 1, FIG. 2 and FIG. 3 is completed. Following these, a deposition process and an etching back process are then performed on the substrate 100, filling in an insulating material (not shown in the drawings) in the space between the conductive pads 180, thereby forming the semiconductor device 10 as shown in FIG. 1, FIG. 2, and FIG. 3.

According to the fabricating method of the semiconductor device 10 in the present embodiment, the first spacer structure 150 and the second spacer structure 160 with materials being at least partially different from each other are formed in various regions (for example being the cell region 100A and the periphery region 100B) on the substrate 100. The first spacer structure 150 for example includes the insulating middle-layer 154, and the second spacer structure 160 for example includes the conductive middle-layer 164, thereby achieving various isolation functions within different regions. Also, since the fabrications of the first spacer structure 150 and the second spacer structure 160 are integrated into the fabricating process of the plugs 170, the formations of the first spacer structure 150 and the second spacer structure 160 are simplified without introducing additional fabricating steps. In this way, the fabricating method of the semiconductor device 10 in the present embodiment is allowable to form the semiconductor device 10 with an optimized structure and functions under a simplified process flow, so as to achieve better operation thereby. After that, a plurality of capacitors (not shown in the drawings) may be further formed over the first plugs 172 of the semiconductor device 10, and the semiconductor device 10 will therefore form a dynamic random access memory device.

Those of ordinary skill in the art should easily realize the semiconductor device and the fabricating method thereof in the present disclosure are not limited to the aforementioned embodiment, and which may include other examples or varieties. The following description will detail the different embodiments of the semiconductor device and the fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

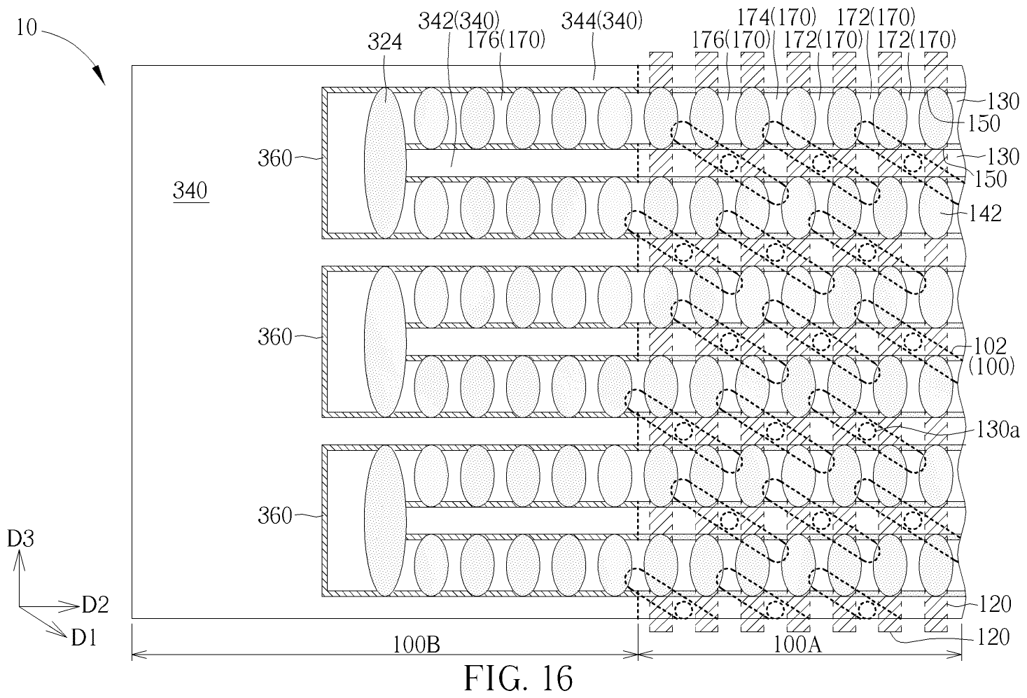

Please refer to FIG. 16, which is a schematic diagram illustrating a top view of a semiconductor device 30 according to a second embodiment of the present disclosure. The structure of the semiconductor device 30 in the present embodiment is substantially the same as that of the semiconductor device 10, as shown in FIG. 1 to FIG. 3, and all the similarities will not be redundantly described hereinafter. The difference between the semiconductor device 30 in the present embodiment and the semiconductor device 10 in the aforementioned embodiment is mainly in that a plurality of dummy bit lines 340 further includes a plurality of first dummy bit lines 342 and a plurality of second dummy bit lines 344 in various extending lengths, such that, second spacer structures 360 disposed on the sidewalls of each dummy bit line 340 will therefore include an U-shaped top-view structure and an I-shaped top-view structure respectively.

Precisely speaking, as shown in FIG. 16, the first dummy bit lines 342 and the second dummy bit lines 344 are respectively extended in the first direction D2, to alternately arrange in the second direction D3. One end of each of the first dummy bit lines 342 is connected to the end-portion of each of the bit lines 130, and another end of each of the first dummy bit lines 342 is connected with one another in the second direction D3. With these arrangements, the second spacer structures 360 disposed on the sidewalls of the first dummy bit lines 342 and the second dummy bit lines 344 will therefore obtain the U-shaped top-view structure and the I-shaped top-view structure correspondingly, and the second spacer structures 360 having the I-shaped top-view structure is right disposed between two opposite sidewalls of the second spacer structures 360 having the U-shaped top-view structure in the second direction D3, but not limited thereto. Besides that, the detailed features like the material and the cross-sectional structure of the second spacer structures 360 in the present embodiment are similar to those of the second spacer structure 160 in the aforementioned embodiment, and all the similarities will not be redundantly described hereinafter. Those of ordinary skill in the art should easily realize the specific features of the second spacer structure 360 in the present embodiment by reference to the cross-sectional view shown in FIG. 3.

According to the semiconductor device 30 in the present embodiment, the first spacer structure 150 and the second spacer structure 360 with materials being at least partially different from each other are also disposed on the sidewalls of the bit lines 130 and the dummy bit lines 340 respectively, for achieving various isolating functions in different regions of the semiconductor device 320. In this way, the structural reliability, as well as the operation performance, of the semiconductor device 30 is dramatically improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate comprising a plurality of active areas;
a plurality of bit lines disposed on the substrate, the bit lines across the active areas;
a plurality of first spacer structures respectively disposed on two opposite sidewalls of each of the bit lines, each of the first spacer structures comprises a multilayer structure; and
a plurality of second spacer structures disposed on the substrate and connected to ends of the first spacer structures respectively, wherein each of the second spacer structures comprises a multilayer structure, one layer of the multilayer structure of the second spacer structures is continuous as one layer of the multilayer structure of the first spacer structures are continuous, and another layer of the multilayer structure of the second spacer structures has a material different from that of another layer of the multilayer structure of the first spacer structures.

2. The semiconductor device according to claim 1, wherein the second spacer structures comprise an U-shaped structure from a top view.

3. The semiconductor device according to claim 2, wherein the second spacer structures comprise an I-shaped structure from a top view.

4. The semiconductor device according to claim 3, wherein the I-shaped structure is disposed between two opposite sidewalls of the U-shaped structure.

5. The semiconductor device according to claim 1, wherein the another layer of the multilayer structure of the second spacer structures comprises a conductive middle-layer, and the another layer of the multilayer structure of the first spacer structures comprises an insulating middle-layer.

6. The semiconductor device according to claim 5, wherein the multilayer structure of the first spacer structures comprises a first spacer layer and a second spacer layer respectively disposed at two sides of the insulating middle-layer, and the multilayer structure of the second spacer structures comprises a third spacer layer and a fourth spacer layer respectively disposed at two sides of the conductive middle-layer, wherein the first spacer layer and the third spacer layer are continuous, and the second spacer layer and the fourth spacer layer are continuous.

7. The semiconductor device according to claim 6, wherein the first spacer layer, the third spacer layer, the second spacer layer, and the fourth spacer layer comprise the same material.

8. The semiconductor device according to claim 5, wherein the insulating middle-layer comprises a first dielectric material and a second dielectric material stacked sequentially in a vertical direction.

9. The semiconductor device according to claim 5, further comprising:
a plurality of first plugs physically contacting each of the active areas, wherein the first plugs and the bit lines are alternately arranged with each other; and
a plurality of second plugs disposed on the substrate without contacting the active areas, wherein the second plugs and the bit lines are alternately arranged with each other, the first spacer structures are respectively disposed between each of the bit lines and each of the first plugs, and the second spacer structures are respectively disposed between each of the bit lines and each of the second plugs.

10. The semiconductor device according to claim 9, wherein each of the second plugs comprises a top surface and a bottom surface in a cross-section, wherein a width of the top surface is smaller than a width of the bottom surface.

11. The semiconductor device according to claim 9, further comprising:
a plurality of dielectric layers respectively disposed on an upper sidewall of each of the second plugs, to physically contact each of the second spacer structures.

12. The semiconductor device according to claim 8, wherein each of the second plugs comprises a first conductive material and a second conductive material stacked in sequence, wherein the first conductive material is the same as a material of the conductive middle-layer.

13. A method of fabricating a semiconductor device, comprising:
providing a substrate, the substrate comprising a plurality of active areas;
forming a plurality of bit lines on the substrate, across the active areas;
forming a plurality of first spacer structures on the substrate, at two opposite sidewalls of each of the bit lines respectively, each of the first spacer structures comprises a multilayer structure; and
forming a plurality of second spacer structures on the substrate, one end of each of the second spacer structures being connected to one end of each of the first spacer structures, wherein each of the second spacer structures comprises a multilayer structure, one layer of the multilayer structure of the second spacer structures is continuous as one layer of the multilayer structure of the first spacer structures are continuous, and another layer of the multilayer structure of the second spacer structures has a material different from that of another layer of the multilayer structure of the first spacer structures.

14. The method of fabricating the semiconductor device according to claim 13, further comprising:
forming a plurality of first plugs respectively contacting each of the active areas, the first plugs being alternately arranged with the bit lines;
forming a plurality of second plugs without contacting the active areas, the second plugs being alternately arranged with the bit lines;
forming the first spacer structure between each of the bit lines and each of the first plugs, the another layer of the multilayer structure of the first spacer structures comprising an insulating middle-layer; and
forming a plurality of dummy bit lines connecting to an end-portion of each of the bit lines, the second spacer structures being formed on sidewalls of the dummy bit lines, the another layer of the multilayer structure of the second spacer structures comprising a conductive middle-layer.

15. The method of fabricating the semiconductor device according to claim 14, wherein forming the second spacer structure further comprises:
sequentially forming a third spacer layer and a second material layer on the sidewalls of each of the dummy bit lines;
forming a spacer material layer on the sidewalls and a top surface of each of the dummy bit lines, and on top surfaces of the third spacer layer and the second material layer.

16. The method of fabricating the semiconductor device according to claim 15, wherein forming the first plugs comprises:
forming a mask layer on the insulating material layer;
removing a portion of the insulating material layer by the mask layer, to form a plurality of plug holes exposing the substrate; and
forming each of the first plugs in each of the plug holes.

17. The method of fabricating the semiconductor device according to claim 16, wherein forming the first spacer structure further comprises:
sequentially forming a first spacer layer, a first material layer, and a second spacer layer on the sidewalls of each of the bit lines, wherein the first spacer and the third spacer are continuous;
partially removing the first material layer to form a first dielectric material; and
forming a second dielectric material on the first dielectric material, wherein the first dielectric material and the second dielectric material stacked in sequence forms the insulating middle-layer.

18. The method of fabricating the semiconductor device according to claim 15, wherein forming the second plugs further comprises:
removing a portion of the insulating material layer, to form a plurality of plug hole without exposing the substrate; and
forming each of the second plugs within each of the plug holes.

19. The method of fabricating the semiconductor device according to claim 18, wherein forming the second spacer structure further comprises:
performing a first etching process, partially removing the portion of the insulating material;
forming a dielectric material layer covering a rest portion of the insulating material layer;
partially removing the dielectric material layer to form a dielectric layer;
partially removing the spacer material layer to expose the top surface of the second material layer; and
preforming a second etching process, further removing the portion of the insulating material and removing the second material layer to form an air-gap layer.

20. The method of fabricating the semiconductor device according to claim 19, wherein forming the second plugs further comprises:
forming a first conductive material within the plug holes, and forming the conductive middle-layer in the air-gap layer; and
forming a second conductive material within the plug holes, wherein each of the second plugs comprises the first conductive material and the second conductive material stacked in sequence.
